(19) United States
(12) Patent Application Publication
(10) Pub. No.: US 2024/0086003 A1
(43) Pub. Date: Mar. 14, 2024

(54) DISPLAY MODULE AND ELECTRONIC DEVICE

(71) Applicant: VIVO MOBILE COMMUNICATION CO., LTD., Dongguan (CN)

(72) Inventors: Guangqi JIA, Dongguan (CN); Le WANG, Dongguan (CN)

(73) Assignee: VIVO MOBILE COMMUNICATION CO., LTD., Dongguan (CN)

(21) Appl. No.: 18/513,468

(22) Filed: Nov. 17, 2023

Related U.S. Application Data
(63) Continuation of application No. PCT/CN2022/092650, filed on May 13, 2022.

(30) Foreign Application Priority Data
May 18, 2021 (CN) 202110542639.2

(51) Int. Cl. G06F 3/041; G02F 1/1362; H10K 59/131; H10K 59/40

(52) U.S. Cl. CPC G06F 3/0414; G02F 1/136286; H10K 59/131; H10K 59/40

(57) ABSTRACT

A display module and an electronic device are provided. The display module includes a display screen, a metal conducting layer, and an insulation protection layer that are stacked sequentially. The insulation protection layer includes at least one via. A side, of the insulation protection layer, facing away from the metal conducting layer is disposed with at least one deformable member, and the deformable member is electrically connected to the metal conducting layer through the via. When pressure is applied on the display screen, the deformable member is deformed and outputs an electrical signal to the metal conducting layer.

### CROSS-REFERENCE TO RELATED APPLICATIONS

This application is a continuation of International Application No. PCT/CN2022/092650, filed on May 13, 2022, which claims priority to Chinese Patent Application No. 202110542639.2, filed May 18, 2021. The entire contents of each of the above-identified applications are expressly incorporated herein by reference.

### TECHNICAL FIELD

This application is directed to the technical field of electronic devices, and in particular, relates to a display module and an electronic device.

### BACKGROUND

With continuous development of terminal devices, advantages of pressure-sensitive buttons become increasingly obvious, as physical buttons are not needed. In some instances, a pressure-sensitive button is mainly used pressure sensing on bezels to implement a corresponding function, to satisfy a specific requirement for human-machine interaction.

However, as there are increasingly more functional requirements on a screen for interaction of a whole machine, an idea of combining a pressure-sensitive button and a screen has emerged. Because a pressure-sensitive module set for pressure-sensitive buttons is stacked up in a direction perpendicular to a screen, a whole electronic device is thick, and user experience is impacted.

### SUMMARY

Embodiments of this application provide a display module and an electronic device.

According to a first aspect, a display module is provided. The display module includes a display screen, a metal conducting layer, and an insulation protection layer. The display screen, the metal conducting layer, and the insulation protection layer are stacked sequentially.

The insulation protection layer includes at least one via, a side, of the insulation protection layer, facing away from the metal conducting layer is disposed with at least one deformable member, and the deformable member is electrically connected to the metal conducting layer through the via.

When pressure is put on the display screen, the deformable member is deformed and outputs an electrical signal to the metal conducting layer.

According to a second aspect, an electronic device is provided. The electronic device includes the display module according to the first aspect.

In embodiments of this application, the display module includes the display screen, the metal conducting layer, and the insulation protection layer. The display screen, the metal conducting layer, and the insulation protection layer are stacked sequentially. The insulation protection layer includes the at least one via. The side, of the insulation protection layer, facing away from the metal conducting layer is disposed with the at least one deformable member, and the deformable member is electrically connected to the metal conducting layer through the via. When pressure is put on the display screen, the deformable member is deformed and outputs the electrical signal to the metal conducting layer. In embodiments of this application, a pressure-sensitive module set may be combined with a display screen, so that an overall thickness can be reduced, to reduce a thickness of the electronic device, thereby further improving user experience.

### BRIEF DESCRIPTION OF DRAWINGS

The accompanying drawings described herein are intended to provide a further understanding of this application, and constitute a part of this application. The illustrative embodiments of this application and descriptions thereof are intended to describe this application, and do not constitute limitations on this application. In the accompanying drawings:

FIG. 1 is a block diagram of a display module according to an embodiment of this application;

FIG. 2 is a block diagram of another display module according to an embodiment of this application;

FIG. 3 is a block diagram of another display module according to an embodiment of this application;

FIG. 4 is a block diagram of another display module according to an embodiment of this application;

FIG. 5 is a block diagram of another display module according to an embodiment of this application;

FIG. 6 is a schematic diagram of positions of four deformable members according to an embodiment of this application;

FIG. 7 is a schematic diagram of a sensing principle according to an embodiment of this application; and

FIG. 8 is a block diagram of another display module according to an embodiment of this application.

### DETAILED DESCRIPTION

The following describes embodiments of this application with reference to the accompanying drawings in embodiments of this application. The described embodiments are some but not all of embodiments of this application. All other embodiments obtained by a person of ordinary skill in the art based on embodiments of this application without creative efforts shall fall within the protection scope of this application.

The terms “first,” “second,” and the like in the description and the claims of this application are used to distinguish between similar objects instead of describing a specific order or sequence. It should be understood that the data used in such a way is interchangeable in proper circumstances so that embodiments of this application can be implemented in an order other than the order illustrated or described herein. In addition, in the description and the claims, “and/or” represents at least one of connected objects, and a character “I” generally represents an “or” relationship between associated objects.

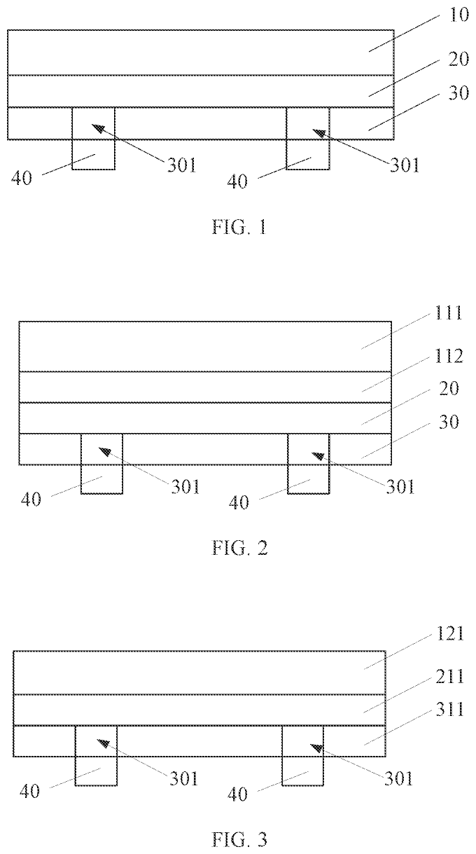

With reference to FIG. 1 to FIG. 7, an electronic device provided in embodiments of this application is described in detail by using specific embodiments and application scenarios of the embodiments.

As shown in FIG. 1, a display module may include a display screen 10, a metal conducting layer 20, and an insulation protection layer 30.

In some implementations, the display screen 10, the metal conducting layer 20, and the insulation protection layer 30 are stacked sequentially. The insulation protection layer 30 includes at least one via 301. A side, of the insulation protection layer 30, facing away from the metal conducting layer 20 is disposed with at least one deformable member 40, and the deformable member 40 is electrically connected to the metal conducting layer 20 through the via 301. When pressure is put on the display screen, the deformable member 40 is deformed and outputs an electrical signal to the metal conducting layer 20.

The deformable member 40 may be a resistor, or may be piezoelectric ceramics or the like. There may be one, two, or more deformable members 40. This is not specifically limited in this embodiment of this application. When there are a plurality of deformable members 40, distribution positions of the deformable members are not limited and are subject to an actual condition.

In some implementations, a display side of the display screen 10 has a target area. When pressure is put on the target area, a pressure-sensitive module set may be deformed. There may be one, two, or more target areas. This is not specifically limited in this embodiment of this application and is subject to an actual condition.

The metal conducting layer 20 may be a coating on the display screen 10, may be stuck to the display screen 10, or the like. The insulation protection layer 30 may be a coating disposed on a side, of the metal conducting layer 20, facing away from the display screen 10, or may be stuck to the metal conducting layer 20. The via 301 may be filled with a conducting material, for example, a metal material or a graphite material. A quantity and position of the via 301 may be determined based on a quantity and position of the deformable member 40. In some implementations, the quantity of the via 301 may be greater than or equal to the quantity of the deformable member 40.

It should be noted that, in addition to the foregoing components, the display module provided in this embodiment of this application, may further include an upper polarizing layer, a glass substrate layer, a filter layer, a lower polarizing layer, a luminescent layer, and the like. This is not described in detail in this embodiment of this application. Different display modules may include different structures.

In this embodiment of this application, the display module may include the display screen 10, the metal conducting layer 20, and the insulation protection layer 30. The display screen 10, the metal conducting layer 20, and the insulation protection layer 30 are stacked sequentially. The insulation protection layer 30 includes the at least one via 301. The side, of the insulation protection layer 30, facing away from the metal conducting layer 20 is disposed with the at least one deformable member 40, and the deformable member 40 is electrically connected to the metal conducting layer 20 through the via 301. When pressure is put on the display screen 10, the deformable member 40 is deformed and outputs the electrical signal to the metal conducting layer 20. In this embodiment of this application, a pressure-sensitive module set may be formed under the screen by using the metal conducting layer 20, the insulation protection layer 30, and the deformable member 40 that are disposed on a side, of the display screen 10, facing away from a display surface, and deformation of the deformable member 40 can generate the electrical signal indicating pressure. In some implementations, a greater magnitude of deformation of the deformable member 40 indicates a larger electrical signal that is output, and indicates greater pressure that the display screen has taken. As a size of the display screen 10 is large, more control modes can be implemented, and more requirements of a user for human-machine interaction can be satisfied, thereby improving user experience. The pressure-sensitive module set is combined with the display screen 10, so that an overall thickness can be reduced, to reduce a thickness of the electronic device, thereby further improving user experience.

As shown in FIG. 2, in an implementation of this application, the display screen 10 may include a display layer 111 and an insulation substrate layer 112.

In some implementations, the insulation substrate layer 112 is disposed on a side, of the metal conducting layer 20, facing away from the insulation protection layer 30, and the display layer 111 is disposed on a side, of the insulation substrate layer 112, facing away from the metal conducting layer 20.

In some implementations, the metal conducting layer 20, the insulation protection layer 30, and the deformable member 40 may form a pressure-sensitive module set, and the pressure-sensitive module set and the display layer 111 of the display screen 10 are insulated by using the insulation substrate layer 112 of the display screen 10. In this way, the pressure-sensitive module set and the display layer 111 are combined, and the pressure-sensitive module set is formed under the screen, so that a plurality of types of pressure-sensitive control can be implemented, to satisfy a plurality of requirements of a user.

As shown in FIG. 3, in an implementation of this application, the display module is an Organic Light-Emitting Diode (OLED).

In some implementations, the display screen 10 includes a display layer 121. The metal conducting layer 20 is an Indium Tin Oxide (ITO) wiring layer of the organic light-emitting diode module, the insulation protection layer 30 is an insulation substrate layer 311 of the organic light-emitting diode module; and when pressure is put on the display screen, the deformable member 40 is deformed and outputs a pressure signal to the ITO wiring layer 211.

In some implementations, when the display module is the OLED screen, the ITO wiring layer 211 of the OLED screen may replace the metal conducting layer 20 of the pressure-sensitive module set, and the insulation substrate layer 311 of the OLED screen may replace the insulation protection layer 30 of the pressure-sensitive module set.

In this embodiment of this application, the metal conducting layer 20 and the insulation protection layer 30 of the pressure-sensitive module set may be replaced with the structures in the OLED screen, to further reduce a thickness of the pressure-sensitive module set, thereby providing better user experience.

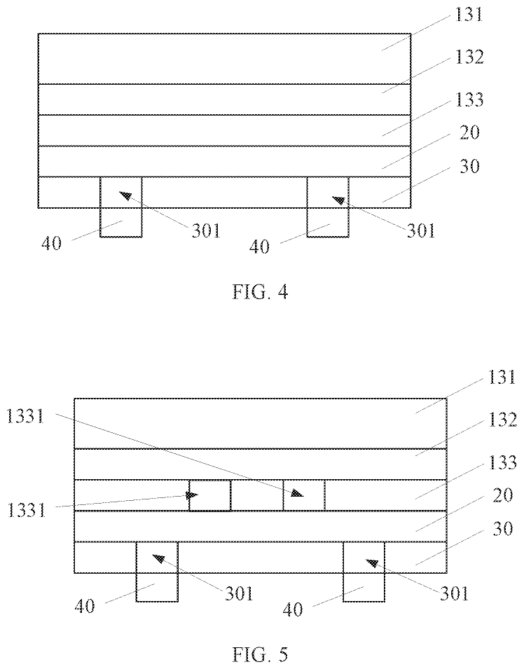

As shown in FIG. 4, in an implementation of this application, the display module is a Liquid Crystal Display (LCD) module.

In some implementations, the display screen 10 includes a display layer 131, a metal grounding layer 132, and an insulation substrate layer 133. The insulation substrate layer 133 is disposed on a side, of the metal conducting layer 20, facing away from the insulation protection layer 30, the metal grounding layer 132 is disposed on a side, of the insulation substrate layer 133, facing away from the metal conducting layer 20, and the display layer 131 is disposed on a side, of the metal grounding layer 132, facing away from the insulation substrate layer 133.

In some implementations, when the display module is the LCD screen, the metal grounding layer 132 of the LCD screen, that is, a metal housing of an in-cell screen, and the metal conducting layer 20 of the pressure-sensitive module set may be insulated by using the insulation substrate layer 133 of the LCD screen. In this way, the pressure-sensitive module set and the display layer are combined, and the pressure-sensitive module set is formed under the in-cell screen, so that a plurality of types of pressure-sensitive control can be implemented, to satisfy a plurality of requirements of a user and reduce a thickness of the pressure-sensitive module set.

In addition to the foregoing structures, the LCD screen may further include a backlight, a light guide film, a polarizer, a liquid crystal layer, and another structure. In some implementations, when the display module is the in-cell screen, there is a metal housing, that is, a metal housing of the in-cell screen, on a side, of a light guide film, facing away from a display surface, as a reference ground for a touchscreen or the like.

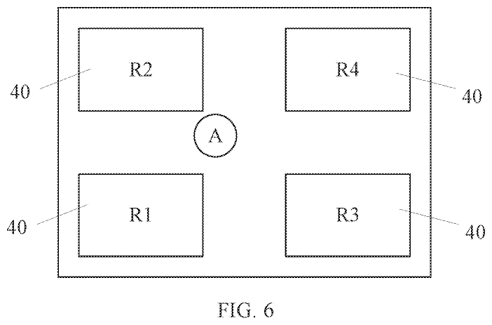

Further, as shown in FIG. 5, the insulation substrate layer may be disposed with at least one grounding via 1331, and the metal conducting layer 20 is electrically connected to the metal grounding layer 132 through the grounding via 1331.

In some implementations, when the display module is the LCD screen, the insulation substrate layer 133 may be disposed with the grounding via 1331, so that the metal grounding layer 132 may be used as a reference ground for the pressure-sensitive module set, to improve an anti-interference capability of the pressure sensitive module set and also improve sensitivity for minor deformation of the deformable member 40, thereby improving detection sensitivity of the pressure-sensitive module set.

The grounding via 1331 may be filled with a conducting material, for example, a metal material or a graphite material. A quantity and position of the grounding via 1331 is not specifically limited in this application and may be determined based on an actual condition.

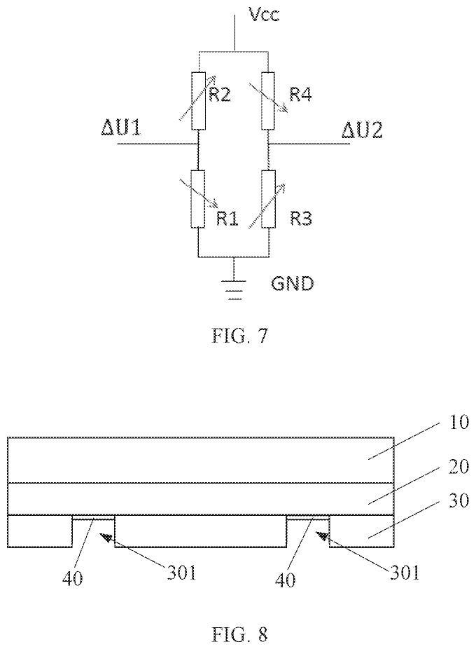

As shown in FIG. 8, in an implementation of this application, the deformable member 40 may be disposed inside the via 301 in the insulation protection layer 30, and the deformable member 40 is directly electrically connected to the metal conducting layer 20.

In some implementations, the deformable member 40 may be added over the metal conducting layer 20 by plating. When pressure is put on the display screen, the pressure is transferred to the deformable member through various layers, to deform the deformable member. The deformation of the deformable member 40 generates a corresponding electrical signal indicating pressure. As the deformable member 40 is inside the via 301, an overall thickness in a direction perpendicular to the display screen can be reduced, to reduce a thickness of the electronic device, thereby further improving user experience.

In another embodiment, the via may be a metal via, and the deformable member 40 is added on a wall of the metal via by plating. When pressure is put on the display screen, the pressure is transferred to the insulation protection layer through various layers, and the insulation protection layer is deformed to deform the deformable member, so that the corresponding electrical signal indicating pressure is generated.

In another embodiment, the deformable member 40 may be disposed in the metal conducting layer 20 by sticking. A length of the deformable member 40 in the direction perpendicular to the display screen 10 may be greater than a thickness of the insulation protection layer 30 in the direction perpendicular to the display screen 10. When pressure is put on the display screen, a part of the deformable member 40 outside the via 301 takes pressure, and the electrical signal is transferred to the metal conducting layer 20. The length of the deformable member 40 in the direction perpendicular to the display screen 10 may alternatively be less than the thickness of the insulation protection layer 30 in the direction perpendicular to the display screen 10. When pressure is put on the display screen, the pressure is transferred to the deformable member through various layers, to deform the deformable member, so that the corresponding electrical signal indicating pressure is generated.

In an implementation of this application, the via 301 in the insulation protection layer 30 may be filled with a conducting material, for example, a metal material or a graphite material. A quantity and position of the via 301 may be determined based on a quantity and position of the deformable member 40.

The deformable member 40 may be electrically connected to the metal conducting layer 20 by using the conducting material, and the deformable member 40 is completely outside the via 301. When pressure is put on the display screen, the whole deformable member is deformed, and the electrical signal is transferred to the conducting layer 20 by using the filled material. As the whole deformable member takes pressure and is deformed, measurement can be more accurate.

Further, a projection of the deformable member 40 is at least partially within a projection of the via 301 in the direction perpendicular to the display screen 10.

In some implementations, the deformable member 40 may be electrically connected to the metal conducting layer 20 by using the conducting material filled in the via 301. In this way, a signal of the electrical connection can be more stable. When pressure is put on the display screen, the pressure can be better transferred to the deformable member 40, so that measurement can be more accurate.

In an implementation of this application, as shown in FIG. 6, there may be four deformable members 40, and correspondingly, there may also be four vias 301. The four deformable members 40 can form a Wheatstone bridge.

In this embodiment of this application, by using the plurality of deformable members 40, sensing of a pressure value can be more accurate, and a pressure change after minor deformation can be sensed.

In some implementations, there may be a plurality of deformable members 40. When pressure is put on the target area, four deformable members 40 that are closest to a pressure trigger point and that have greatest magnitude of deformation may be selected from the plurality of deformable members 40 to form a Wheatstone bridge.

Because of deformation of the target area, each of the deformable members 40 is deformed, with differences in magnitude of deformation and direction. When pressure is transferred to the deformable member 40 through the metal conducting layer and the via from above to below in the direction perpendicular to the display screen 10, deformable members 40 at different positions have different magnitudes of deformation because of uneven pressure, and different voltage variables are generated. A magnitude of a voltage variable depends on a distance between the deformable member and a position of a pressure trigger point A. A shorter distance from the pressure trigger point indicates a greater magnitude of deformation, and a pressure value deceases from the pressure trigger point roughly circularly from an inner side to an outer side. In this case, the pressure value may be calculated based on a voltage change value converted from a magnitude of deformation of the deformable member 40.

For example, as shown in FIG. 6 and FIG. 7, GND means grounding. The four deformable members 40 that form the Wheatstone bridge are four resistors R1, R2, R3, and R4. A voltage change of the Wheatstone bridge is as shown in the following formula. The voltage change value, that is, an output signal, may be calculated according to the following formula, and then converted into the pressure value.

$$\begin{matrix}Δ U 1 = \frac{{V}_{c c}^{*} ( R 1 + Δ {R}_{1} )}{R 1 + R 2 + Δ {R}_{1} + Δ {R}_{2}} \\ Δ U 2 = \frac{{V}_{c c}^{*} ( R 3 + Δ {R}_{3} )}{R 3 + R 4 + Δ {R}_{3} + Δ {R}_{4}} \\ Δ U = Δ U 1 - Δ U 2\end{matrix}$$

V_{cc} is a power supply voltage; is a resistance value of the first resistor R1; ΔR₁ is a resistance change after the first resistor R1 has deformation; R2 is a resistance value of the second resistor R2; ΔR₂ is a resistance change after the second resistor R2 has deformation; R3 is a resistance value of the third resistor R3; ΔR₃ is a resistance change after the third resistor R3 has deformation; R4 is a resistance value of the fourth resistor R4; ΔR₄ is a resistance change after the fourth resistor R4 has deformation; ΔU1 is a voltage difference between R1 and R2; ΔU2 is a voltage difference between R3 and R4; and ΔU is the output signal.

In an implementation of this application, the metal conducting layer 20 may be plating on the display screen 10.

In some implementations, the metal conducting layer 20 may be metal plating on the display screen 10.

In some implementations, an embodiment of this application further provides an electronic device, including the display module provided in any one of the foregoing embodiments. The electronic device may implement any function of the display module. This is not specifically limited in this embodiment of this application.

The electronic device in this application may be a full-screen mobile phone, a tablet computer, or another device. Details are not described in this application and are subject to an actual condition.

It should be noted that, in this specification, the term “include,” “comprise,” or any other variant thereof is intended to cover a non-exclusive inclusion, so that a process, a method, an article, or an apparatus that includes a list of elements not only includes those elements but also includes other elements which are not expressly listed, or further includes elements inherent to such process, method, article, or apparatus. In absence of more constraints, an element preceded by “includes a . . . ” does not preclude the existence of other identical elements in the process, method, article, or apparatus that includes the element. Furthermore, it should be noted that the scope of the methods and apparatuses in the implementations of this application is not limited to performing the functions in the order shown or discussed, but may also include performing the functions in a substantially simultaneous manner or in a reverse order depending on the functions involved. For example, the described methods may be performed in an order different from that described, and various steps may be added, omitted, or combined. In addition, features described with reference to some examples may be combined in other examples.

According to the descriptions of the foregoing implementations, a person skilled in the art may clearly understand that the foregoing method embodiments may be implemented by using software and a required universal hardware platform, or certainly may be implemented by using hardware. Based on such an understanding, the technical solutions of this application essentially or the part contributing to the related art may be implemented in a form of a software product. The computer software product is stored in a storage medium (such as a ROM/RAM, a hard disk, or an optical disc), and includes several instructions for instructing a terminal (that may be a mobile phone, a computer, a server, an air conditioner, a network device, or the like) to perform the methods described in embodiments of this application.

Embodiments of this application are described with reference to the accompanying drawings. However, this application is not limited to the foregoing specific implementations. The foregoing specific implementations are merely examples, but are not limiting. Under the enlightenment of this application, a person of ordinary skill in the art may make many forms without departing from the objective and the scope of the claims of this application, and these forms all fall within the protection scope of this application.

1. A display module, comprising:
a display screen;
a metal conducting layer; and
an insulation protection layer, wherein:
the display screen, the metal conducting layer, and the insulation protection layer are stacked sequentially;
the insulation protection layer comprises at least one via;
a side of the insulation protection layer facing away from the metal conducting layer is disposed with at least one deformable member, and the deformable member is electrically connected to the metal conducting layer through the via; and
when pressure is applied on the display screen, the deformable member is deformed and outputs an electrical signal to the metal conducting layer.

2. The display module according to claim 1, wherein the display screen comprises a display layer and an insulation substrate layer, and
wherein the insulation substrate layer is disposed on a side of the metal conducting layer facing away from the insulation protection layer, and the display layer is disposed on a side of the insulation substrate layer facing away from the metal conducting layer.

3. The display module according to claim 1, wherein:
the display module is an organic light-emitting diode module;
the display screen comprises a display layer;
the metal conducting layer is an indium Tin Oxide (ITO) wiring layer of the organic light-emitting diode module;
the insulation protection layer is an insulation substrate layer of the organic light-emitting diode module; and
when pressure is applied on the display screen, the deformable member is deformed and outputs a pressure signal to the ITO wiring layer.

4. The display module according to claim 1, wherein:
the display module is a liquid crystal display module;
the display screen comprises a display layer, a metal grounding layer, and an insulation substrate layer;
the insulation substrate layer is disposed on a side of the metal conducting layer facing away from the insulation protection layer;
the metal grounding layer is disposed on a side of the insulation substrate layer facing away from the metal conducting layer; and
the display layer is disposed on a side of the metal grounding layer facing away from the insulation substrate layer.

5. The display module according to claim 1, wherein the via is filled with a conducting material.

6. The display module according to claim 5, wherein a projection of the deformable member is at least partially within a projection of the via in a direction perpendicular to the display screen.

7. The display module according to claim 1, wherein the deformable member is disposed in the via.

8. The display module according to claim 4, wherein the insulation substrate layer is disposed with at least one grounding via, and the metal conducting layer is electrically connected to the metal grounding layer through the grounding via.

9. The display module according to claim 1, comprises at least four deformable members, and four vias, wherein the four deformable members form a Wheatstone bridge.

10. The display module according to claim 1, wherein the metal conducting layer is plating on the display screen.

11. An electronic device, comprising a display module, wherein the display module comprises:
a display screen;
a metal conducting layer; and
an insulation protection layer, wherein:
the display screen, the metal conducting layer, and the insulation protection layer are stacked sequentially;
the insulation protection layer comprises at least one via;
a side of the insulation protection layer facing away from the metal conducting layer is disposed with at least one deformable member, and the deformable member is electrically connected to the metal conducting layer through the via; and
when pressure is applied on the display screen, the deformable member is deformed and outputs an electrical signal to the metal conducting layer.

12. The electronic device according to claim 11, wherein the display screen comprises a display layer and an insulation substrate layer, and
wherein the insulation substrate layer is disposed on a side of the metal conducting layer facing away from the insulation protection layer, and the display layer is disposed on a side of the insulation substrate layer facing away from the metal conducting layer.

13. The electronic device according to claim 11, wherein:
the display module is an organic light-emitting diode module;
the display screen comprises a display layer;
the metal conducting layer is an Indium Tin Oxide (ITO) wiring layer of the organic light-emitting diode module;
the insulation protection layer is an insulation substrate layer of the organic light-emitting diode module; and
when pressure is applied on the display screen, the deformable member is deformed and outputs a pressure signal to the ITO wiring layer.

14. The electronic device according to claim 11, wherein:
the display module is a liquid crystal display module;
the display screen comprises a display layer, a metal grounding layer, and an insulation substrate layer;
the insulation substrate layer is disposed on a side of the metal conducting layer facing away from the insulation protection layer;
the metal grounding layer is disposed on a side of the insulation substrate layer facing away from the metal conducting layer; and
the display layer is disposed on a side of the metal grounding layer facing away from the insulation substrate layer.

15. The electronic device according to claim 11, wherein the via is filled with a conducting material.

16. The electronic device according to claim 15, wherein a projection of the deformable member is at least partially within a projection of the via in a direction perpendicular to the display screen.

17. The electronic device according to claim 11, wherein the deformable member is disposed in the via.

18. The electronic device according to claim 14, wherein the insulation substrate layer is disposed with at least one grounding via, and the metal conducting layer is electrically connected to the metal grounding layer through the grounding via.

19. The electronic device according to claim 11, wherein the display module comprises at least four deformable members, and four vias, wherein the four deformable members form a Wheatstone bridge.

20. The electronic device according to claim 11, wherein the metal conducting layer is plating on the display screen.
